(19) United States
(12) Patent Application Publication
(10) Pub. No.: US 2026/0043881 A1
(43) Pub. Date: Feb. 12, 2026

(54) MR Data Acquisition Using Dual Readout Windows and Steady-State Excitation with Fat Saturation

(71) Applicant: Siemens Healthineers AG, Forchheim (DE)

(72) Inventors: Dominik Paul, Bubenreuth (DE); Flavio Carinci, Würzburg (DE); Mario Zeller, Erlangen (DE)

(73) Assignee: Siemens Healthineers AG, Forchheim (DE)

(21) Appl. No.: 19/289,320

(22) Filed: Aug. 4, 2025

(30) Foreign Application Priority Data
Aug. 6, 2024 (DE) 10 2024 207 452.7

(51) Int. Cl. G01R 33/561; G01R 33/48

(52) U.S. Cl. CPC G01R 33/5613; G01R 33/4818; G01R 33/5617

(57) ABSTRACT

Computer-implemented method for recording MR data, including: executing a MR sequence having a sequence segment maintained in a steady state by regular excitation modules, each excitation module including an excitation pulse; for each excitation module, providing: a first read-out time window for measuring MR data of a free induction decay; and a second read-out time window, occurring after a last excitation module by at least a duration of the first read-out time window, the last excitation module acting as a refocusing module for the penultimate excitation module, wherein both read-out time windows follow an excitation module and are used to measure MR data of a spin echo; and outputting, in a preparation period between a pair of excitation modules comprising a beginning excitation module and a concluding excitation module that follow one another in the MR sequence, a fat saturation module including a RF fat saturation pulse.

### TECHNICAL FIELD

The aspects of the disclosure relate to a computer-implemented method for recording magnetic resonance data with a magnetic resonance device, wherein a magnetic resonance sequence is used, in which during a steady state in a sequence segment which is maintained by regular excitation modules with at least one excitation pulse, a first read-out time window for measuring magnetic resonance data of a free induction decay and also a second read-out time window which is distanced from a last excitation module by at least the first read-out duration of the first read-out time window, said last excitation module acting as a refocusing module for the penultimate excitation module, both of which read-out time windows immediately follow an excitation module, are used to measure magnetic resonance data of a spin echo. Moreover, the aspects of the disclosure relate to a magnetic resonance device, a computer program, and an electronically readable data carrier.

### BACKGROUND

Magnetic resonance imaging has since become an established imaging tool above all in medicine. Generally speaking, with magnetic resonance imaging spins are aligned in a strong main magnetic field and deflected from this alignment by means of radio frequency excitation pulses so that a precession results in particular. The precession can be measured as magnetic resonance signals, wherein gradient pulses are used for spatial resolution. In this regard, the embodiment of the pulses and the temporal course typically determines a magnetic resonance sequence. The magnetic resonance sequence in this regard typically also determines the weighting, wherein main types of weighting comprise the proton density weighting, the T1 weighting, the T2 weighting and the T2* weighting. Different types of magnetic resonance sequences have already been proposed in the prior art and are suited to various specific applications.

By way of example, for the purpose of examining joints of a patient, conventional proton density-weighted and/or T2-weighted magnetic resonance data are frequently recorded and corresponding magnetic resonance images reconstructed. Other widespread recording techniques have, however, also been proposed, the magnetic resonance sequences of which are based on gradient echo recordings (GRE recordings). Hybrid methods are also already known in the prior art.

One of these methods uses what is known as a DESS sequence (“double echo steady state” sequence) as a magnetic resonance sequence. Herein, two echoes, namely a free induction decay (FID, as gradient echo) and a spin echo (SE), are recorded in a time-delayed manner and are produced by the same excitation. The entire recording process can be understood to be a very long echo train, such as is typically in magnetic resonance sequences, which use a steady state. The FID echo is produced directly by means of the excitation following an excitation module and is measured using the gradient pulses known in this regard. The associated first read-out time window therefore begins immediately after the excitation module, which comprises at least one radio frequency excitation pulse. The special feature in the DESS sequence is the measurement of the spin echo, which is produced from the FID echo by refocusing by means of the next excitation module. The second read-out time window for the magnetic resonance data of the n-th spin echo adjoins the first read-out time window in the DESS sequence, said first read-out time window being assigned to the (n+1)-th FID echo. This means that two read-out time windows, namely a first and a second read-out window, follow at least each non-first or non-last excitation module.

The DESS sequence can advantageously be used to assess the cartilage, in particular with respect to structure, thickness, damage, and suchlike. Reference is made purely by way of example in this context to the article “The osteoarthritis initiative: report on the design rationale for the magnetic resonance imaging protocol for the knee” by C. G. Peterfy et al. in Magnetic Resonance Imaging 38 (2017), pages 63 to 70.

With the recording with the DESS sequence or related magnetic resonance sequences, the signal of the spins of protons (water spins) bound in water is essentially relevant, while the signal of the spins of protons (fat spins) bound in fat is not to be imaged. It is therefore known in the prior art to use a water excitation (WE) in the excitation module, in order to suppress the unwanted fat signal. In order to excite water spins in a frequency-selective manner, so-called composite pulses, which consist of several subpulses, are used here in particular. While the flip angle of the water spins accumulate over time as a result of the subpulses, a flip angle of zero results for the fat spins. Conventional fat saturation techniques, for instance SPAIR or STIR, which operate with delay times, cannot be used since a steady state is used in the magnetic resonance sequence, which is not to be interrupted.

The water excitation nevertheless has certain disadvantages, for instance, the duration which is increased with the use of composite pulses, the B1 sensitivity (radio frequency field sensitivity), and the dependency on the homogeneity of the main magnetic field (B0 field).

### SUMMARY

An object underlying the aspects of the disclosure is therefore to provide a possibility for improved suppression of the fat signal in the DESS sequence and comparable sequences which disturb the steady state as little as possible.

In order to achieve this object, a computer-implemented method, a magnetic resonance device, a computer program, and an electronically readable data carrier according to the subordinate claims are provided in accordance with the aspects of the disclosure. Advantageous developments become apparent from the subclaims.

With a method of the type cited in the introduction, provision is made in accordance with the aspects of the disclosure for a fat saturation module with at least one radio frequency fat saturation pulse to be output between at least one pair comprising a beginning excitation module and a concluding excitation module which follow one another in the magnetic resonance sequence in a preparation period.

It is therefore proposed to suspend the measurements and instead to output a fat saturation module at least between a pair of excitation modules, typically between several pairs of excitation modules, said fat saturation module saturating the magnetization of the fat spins and thus suppressing the fat signal. This means that no measurement takes place in the preparation period. Nevertheless, the interval between the excitation modules is expediently constant to maintain the steady state, and thus the steady state itself is maintained.

With a sufficiently long echo time or interval from excitation module to excitation module, it is basically possible, particularly in respect of the gradient pulses, to produce the following spin echo in usable form despite the saturation module. However, short echo times are typically employed, meaning that the gradient scheme in the preparation period is not maintained.

An expedient development then provides for the second read-out time window following the excitation module concluding the preparation period and/or the first read-out time window preceding the excitation module beginning the preparation period or following the concluding excitation module to be omitted and/or the magnetic resonance data recorded therein to be rejected. This prevents unsuitable magnetic resonance data from being included in reconstructed magnetic resonance images on account of the incorrect gradient scheme in the preparation period. With the omission of magnetic resonance data of a second read-out time window, a first read-out time window or its magnetic resonance data can accordingly expediently also be omitted. The sampling of the k-space is to be adjusted accordingly in order to obtain complete sets of magnetic resonance data in each case. Here it may be expedient for the first read-out time window following the concluding excitation module to be allowed to be omitted or to reject its magnetic resonance data. The time interval following the concluding excitation module can be summarized as a type of “dummy echo”.

It should be noted that as a function of the intensity of the disturbance introduced into the gradient scheme or possibly generally the steady state, a number of such “dummy echo” periods may also follow the preparation period. This is typically not necessary, however.

The magnetic resonance sequence is in particular a DESS sequence. In this, as already shown, precisely one first read-out time window, in which magnetic resonance data of the free induction decay is recorded and precisely one second read-out time window, in which magnetic resonance data of the spin echo is recorded, typically follow an excitation module. If the corresponding echo is not present or it is not to be recorded or processed further, the read-out time window is typically used, and the recorded magnetic resonance data is then rejected. It is naturally also conceivable, as described for the scope of the preparation period, to omit read-out time windows entirely.

The excitation pulses are, like the fat saturation pulses, naturally radio frequency pulses (RF pulses). Here, gradient pulses, in particular at least one slice selection gradient pulse and/or at least one phase encoding gradient pulse and/or at least one read-out gradient pulse, are also used in the magnetic resonance sequence in the excitation modules and the read-out time windows. At least one gradient pulse, in particular at least one crusher gradient pulse, should more detail be given, can also be included in the fat saturation module, as essentially known.

In summary, it is proposed to integrate fat saturation pulses in the sequence segment or echo train, wherein the steady state is not interrupted. An improved suppression of the fat signal can be achieved in this way.

In an expedient development, provision can be made for a preparation period directly after the first output excitation module of each sequence segment to be used as an excitation module which begins the preparation period. In this way, a suppression of the fat signal by means of the fat saturation module is already achieved at the start.

Alternatively or in addition, provision can also be made for a preparation module serving the fat saturation to precede the sequence segment. This can then also be configured differently to the fat saturation module of the preparation period, for instance, use a SPAIR technique (spectral pre-saturation attenuated inversion recovery) and/or a STIR technique (short time inversion recovery). Both with SPIR and also with SPAIR, fat spins are essentially selectively excited by an inversion pulse as a fat saturation pulse, followed by a spoiler gradient pulse. The single key difference between SPAIR and SPIR is the type of inversion pulses since SPAIR uses an adiabatic pulse. Since processing occurs here before or at the start of the sequence segment, there is still no steady state, and there is in particular the possibility of using delay times in the fat saturation techniques.

The at least one excitation pulse of each excitation module can preferably be embodied to restrict the excitation to spins of protons bound in water. A so-called water excitation pulse, WE pulse, can thus be used. In particular, a composite pulse can be used in the excitation modules, which composite pulse comprises several, for instance, three or five, subpulses, in which the flip angle achieved for water spins accumulates on the desired overall flip angle and is added back to zero for fat spins. However, composite pulses of this type result in a longer duration of the excitation module, but by combining the usage of the fat saturation module and a water excitation, it is not only the general advantage of an improved suppression of the fat signal that develops but a larger bandwidth in the main magnetic field (B0 field) can instead be covered for the fat saturation.

In particular, if shorter excitation modules are desired, it may, however, also be expedient to use non-spin type-selective (in other words, normal) excitation pulses.

A preferred development of the present aspects of the disclosure provides that the fat saturation pulse is output centrally between the beginning and the concluding excitation module and/or that the fat saturation module comprises a crusher gradient pulse which follows the fat saturation pulse. In this regard, with the use of a crusher gradient pulse, it is preferred to place the fat saturation pulse outside of the center, for instance up to a third of the preparation period, and the crusher gradient pulse up to a second third of the preparation period. The fat saturation pulse is generally particularly advantageously a frequency-selective radio frequency excitation pulse which is matched to the resonance frequency of the fat spins, the flip angle of which is ideally at least essentially 90°. The crusher gradient pulse then obtains the wanted magnetic resonance signal of the water spins (with a longitudinal magnetization) and destroys the unwanted magnetic resonance signals of the fat spins (with transversal magnetization). If a crusher gradient pulse is not used, the other gradient pulses played out in the further course of the sequence segment, for instance, the excitation module and/or the following read-out time window, act additionally as crusher gradients. For a reliable effect, a dedicated crusher gradient pulse is, however, particularly preferred as part of the fat saturation module. The crusher gradient pulse can have a high intensity here. It is in particular the only gradient pulse of the fat saturation module. The crusher gradient pulse can be played out along at least one gradient direction, in particular along at least two gradient directions. When played out along a number of gradient directions, the intensity of the crusher gradient pulse can be distributed among the gradient axes. In particular, the gradient directions correspond to physical gradient axes provided by corresponding gradient coils of the magnetic resonance device.

In general, a technique based on the chemical shift between spins of protons bound in fat and in water can be used as a fat saturation technique. Provision can be made by way of example for a simple frequency-selective fat excitation pulse which is not embodied as a composite pulse to be used as the fat saturation pulse. The fat saturation pulse can be output rapidly. It results, as described, preferably in a flip angle of essentially 90°. The transversal magnetization produced then is ideally cancelled out again by the at least one crusher gradient pulse. The fat saturation pulse is, as already indicated, preferably not spatially selective so that the crusher gradient pulse preferably forms the single gradient pulse of the fat saturation module.

Provision can expediently be made for a preparation period of the several preparation periods to be provided in each case after a predetermined number of excitation modules. For instance, the predetermined number can amount to 10 to 50. This achieves an equal distribution and thus, in particular, uniform maintenance of the effect of the fat saturation module. A regular application of the preparation period of this type, in particular, therefore, all n excitation modules, thus ensures a robust fat saturation over the duration of the sequence segment, which can comprise a few 1000 excitation modules, for instance.

Preferred exemplary embodiments of the present aspects of the disclosure can also provide an irregular application of the fat saturation module or of preparation periods. Provision can be made particularly advantageously for a preparation period of the several preparation periods always then to be used if the k-space center is passed in the k-space to be sampled at least with respect to one direction. This can refer to this passage being imminent. The at least one direction can be here in particular a phase-encoding direction, in particular the k_{y}-direction. In other words, the fat saturation module is always output in the vicinity of the k-space center, in the reordering preferably at least with respect to k_{y}. This allows a particularly good fat saturation effect to be achieved, since it is always available anew when the main signal-transmitting central portion of the k-space is sampled.

Exemplary embodiments are also conceivable, in which at least one of the preparation periods is placed at least partially at random in the sequence segment. A pseudo-randomization or a restricted randomization, for instance, a random number added to a basic regularity, is preferably used in order to achieve the most uniform maintenance of the fat saturation possible.

In addition to the method, the present aspects of the disclosure also relate to a magnetic resonance device, having a control device embodied to carry out the inventive method. All embodiments relating to the inventive method can be transferred analogously to the inventive magnetic resonance device and vice versa, so that the advantages already cited can also be achieved with the magnetic resonance device.

The magnetic resonance device has, in particular, as is essentially known, a main magnet unit, which accommodates the in particular superconducting main magnet generating the main magnetic field and can have a, in particular cylindrical patient receptacle into which the patient can be moved by means of a patient couch for examination purposes. A gradient coil arrangement and/or a radio frequency coil arrangement can be provided so as to surround the patient receptacle. Local coil arrangements can also be used as a radio frequency coil arrangement.

The control device has at least one processor and at least one storage means. Functional units can be formed by means of hardware and/or software in order to control the operation of the magnetic resonance device. In particular, the control device can have a sequence unit which controls the recording operation of the magnetic resonance device and, in this process, actuates in particular the gradient coil arrangement and the radio frequency coil arrangement according to a magnetic resonance system for outputting gradient pulses and radio frequency pulses. The magnetic resonance sequence can be provided and/or compiled by a configuration unit. By way of example, provision can be made specifically for the configuration unit to be embodied to provide and/or compile a magnetic resonance sequence, in which during a steady state in a sequence segment, which is maintained by regular excitation modules with at least one excitation pulse, a first read-out time window for measuring magnetic resonance data of a free induction decay and also a second read-out time window which is distanced from a last excitation module by at least the first read-out duration of the first read-out time window, said last excitation module acting as a refocusing module for the penultimate excitation module, both of which immediately follow an excitation module, are used to measure magnetic resonance data of a spin echo and moreover, a fat saturation module with at least one radio frequency fat saturation pulse is output between at least one pair comprising a beginning excitation module and a concluding excitation module, which follow one another, in the magnetic resonance sequence in a preparation period. The sequence unit can be embodied to receive magnetic resonance data according to the sequence.

An inventive computer program can be loaded directly into a storage means of a control device of a magnetic resonance device and has program means such that upon execution of the computer program on the control device, this is prompted to carry out the steps of an inventive method. The computer program can be stored on an inventive electronically readable data carrier, which has control information stored thereupon that comprises at least one inventive computer program and is embodied so that upon use of the data carrier in a control device of a magnetic resonance device, this is embodied to carry out an inventive method. The data carrier is preferably a non-transient data carrier, for instance a CD ROM.

### BRIEF DESCRIPTION OF THE DRAWINGS

Further advantages and details of the present aspects of the disclosure result from the exemplary embodiments described below and on the basis of the drawings, which show:

FIG. 1 illustrates a cutout of a sequence diagram of a conventional DESS sequence according to the prior art,

FIG. 2 illustrates a diagram to explain the measurement of the spin echo in the DESS sequence,

FIG. 3 illustrates a cutout of a sequence diagram of a DESS sequence according to the present aspects of the disclosure,

FIG. 4 illustrates a flow chart of an exemplary embodiment of the inventive method,

FIG. 5 illustrates a schematic diagram of an inventive magnetic resonance device, and

FIG. 6 illustrates a functional design of a control device of the magnetic resonance device.

### DETAILED DESCRIPTION

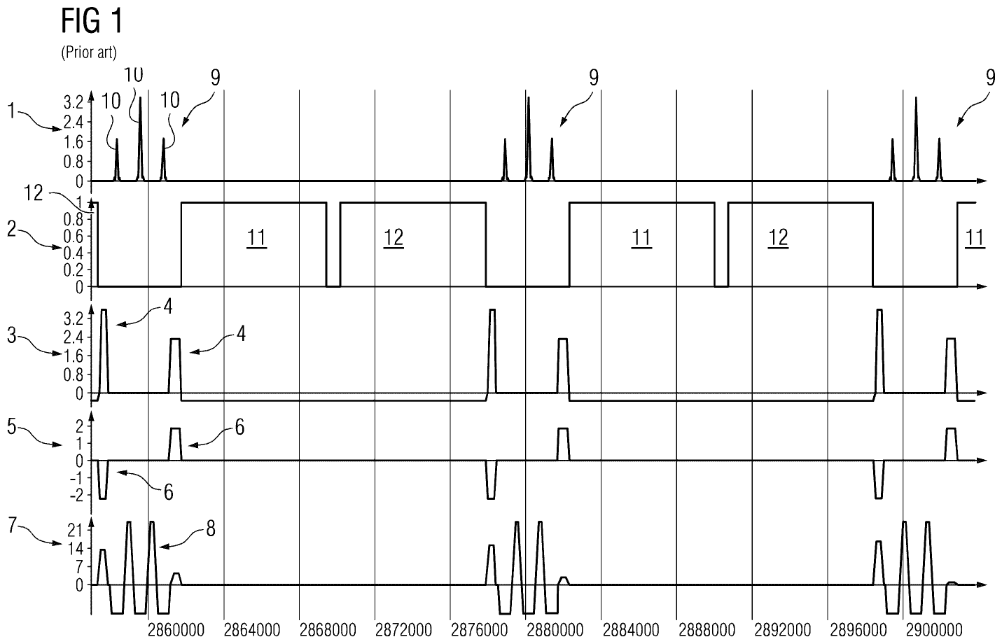

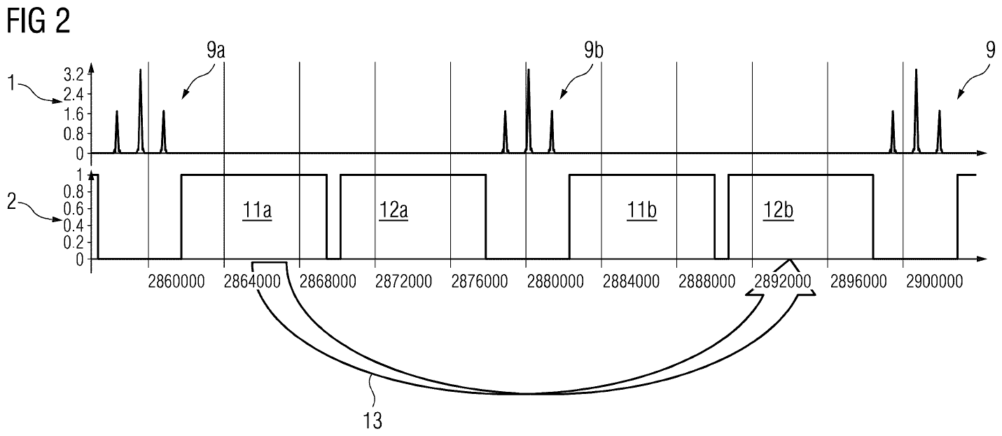

FIG. 1 shows a cutout of a sequence diagram of a DESS sequence according to the prior art, while FIG. 2 is used for a more detailed explanation. Radio frequency activities are shown in a first topmost graph 1, read-out activities are shown in the next graph 2, gradient pulses 4 in a first gradient direction (physical gradient axis x-readout gradient) are shown in the middle graph 3, gradient pulses 6 in a second gradient direction (gradient axis y-phase encoding direction) are shown in the next graph 5 and gradient pulses 8 in a third gradient direction (gradient axis z-slice selection or partition direction) are shown in the lowermost graph 7.

Here, FIG. 1 shows a portion of a sequence segment, in which a steady state is maintained by excitation modules 9 output at equal time intervals. In this regard, each excitation module 9 uses a composite pulse with by way of example, with three subpulses 10 as a radio frequency excitation pulse. The composite pulse is embodied to realize a water excitation (WE) such that an effective flip angle is only produced for water spins and not for fat spins, however. Two read-out time windows 11, 12, namely a first read-out time window 11 for measuring magnetic resonance data of an FID signal and a second read-out window 12 for measuring magnetic resonance data of a spin echo signal clearly follow each excitation module 9.

FIG. 2 explains the measurement of an echo signal in the context of the DESS sequence. As indicated by the arrow 13, the spin echo, which is measured in the second read-out time window 12b, develops from the FID echo, which is measured in the first read-out time window 11a, by means of refocusing by the next excitation module 9b. In other words, the FID echo number “i” is measured in the first read-out window 11a, the spin echo “i−1” in the second read-out window 12a and the FID echo “i+1” in the first read-out time window 11b and the spin echo “i” in the second read-out time window 12b.

A further suppression of the fat signal is not provided in the DESS sequence in FIG. 1.

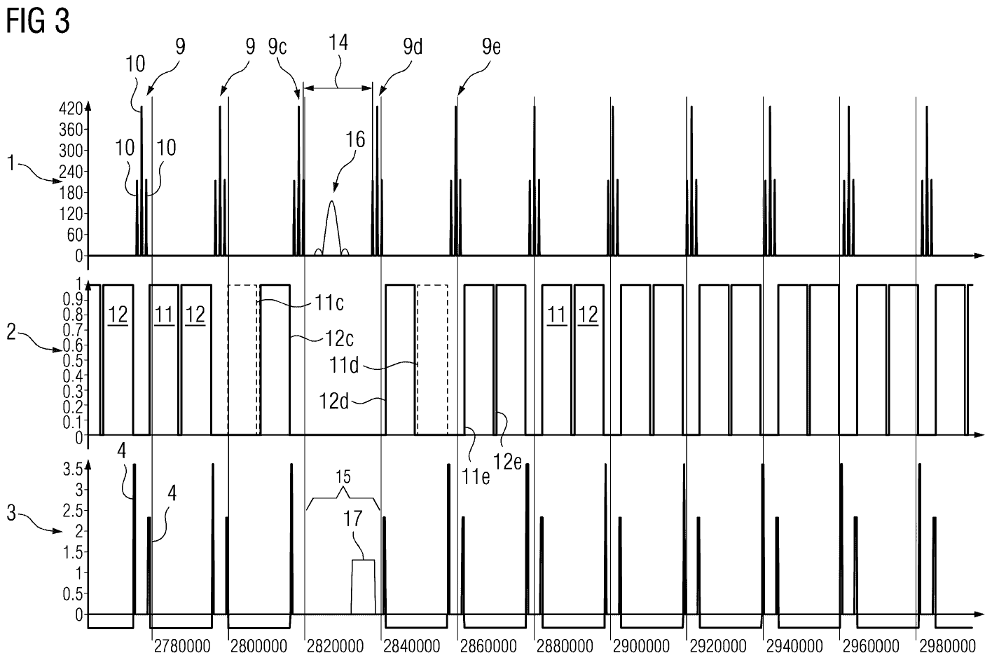

FIG. 3 shows a cutout of the sequence diagram of a DESS sequence used as the magnetic resonance sequence in an inventive method, in which DESS sequence corresponding components relating to the DESS sequence in FIG. 1 are provided with the same reference characters, and for the sake of clarity, only graphs 1, 2, and 3 are shown.

Evidently, no measurements take place between the excitation modules 9c and 9d, but a preparation period 14 is provided in which a fat saturation module 15 is output. The excitation module 9c defines the beginning of the preparation period 14 and is therefore referred to as beginning excitation module 9c, the excitation module 9d decides the preparation period 14 with its beginning and is therefore referred to as concluding excitation module 9d.

In the present exemplary embodiment, the fat saturation module 15 comprises a fat saturation pulse 16, which is designed here as a simple frequency-selective radio frequency excitation pulse that relates to the fat spins, in other words, not as a composite pulse, with a flip angle of 90°. A crusher gradient pulse 17, which once again cancels out the signal of the transversal magnetization of the fat spins produced by the fat saturation pulse 16, follows the fat saturation pulse 16, but does not touch the longitudinal magnetization of the water spins in the steady state. The crusher gradient pulse can also be omitted in other exemplary embodiments. It does not necessarily have to be output in the read-out direction; instead, in addition or alternatively, it can also be output in one or both other gradient directions.

By means of the preparation period 14, the gradient scheme is interrupted and no spin echo is measured there. Therefore, on the one hand, no (meaningfully measurable) spin echo develops in the second read-out time window 12d; on the other hand, no spin echo is measured relating to the FID echo in the first read-out time window 11c. Therefore, in the exemplary embodiment currently shown, the read-out time windows 11c and 12d are omitted, or the magnetic resonance data measured there (to simplify the process) is rejected. Alternatively to the first read-out time window 11c, the first read-out time window 11d can also be omitted or its magnetic resonance data rejected, so that the time interval between the excitation modules 9d and 9e can also be understood to mean “dummy echo”. In any case, the spin echo of the second read-out time window 12e is the refocusing result of the FID echo of the first read-out time window 12d.

Such a preparation period 14 can expediently also be provided after the first ever excitation module 9 of the sequence segment in order to cause a fat saturation right at the start. Alternatively or in addition, another preparation module serving for fat saturation can also precede the sequence segment, which can use a SPAIR technique or a STIR technique, for instance.

In the present exemplary embodiment shown, preparation periods 14 are provided at regular intervals in the sequence segment, for instance in each case after a predetermined number of excitation modules 9, which may amount in particular to between 10 and 50. Irregular preparation periods 14 are conceivable to a certain extent, which ensures a uniform fat saturation at least in terms of approach or fat saturation, which is available at least with relevant measurements. For instance, provision can then always be made for a preparation period 14 if the k-space center is passed in at least one direction, in particular at least the k_{y} direction.

It should finally be noted again that the excitation modules 9 in the present exemplary embodiment in turn comprise water excitations as a result of composite pulses. Exemplary embodiments in which the excitation pulses of the excitation modules 9 are not composite pulses or are absolutely not spin type-selective are also conceivable.

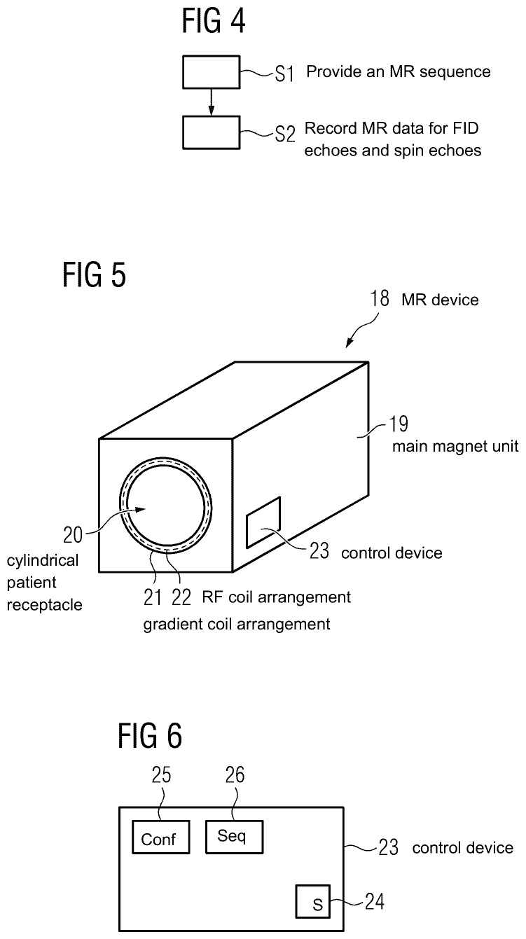

FIG. 4 shows a flow chart of an exemplary embodiment of the method according to the aspects of the disclosure. In this regard, in a step S1, the magnetic resonance sequence described with respect to FIG. 3, here DESS sequence, is provided or compiled. In a step S2, it is then used to record magnetic resonance data for FID echoes and spin echoes with the magnetic resonance device.

FIG. 5 shows a schematic diagram of an inventive magnetic resonance device 18. The magnetic resonance device 18 comprises a main magnet unit 19, which comprises the superconducting main magnet (not shown). A cylindrical patient receptacle 20 is provided in the main magnet unit 19, into which receptacle a patient can be moved by means of a patient couch not shown here in more detail. A gradient coil arrangement 21 and a radio frequency coil arrangement 22 are provided surrounding the patient receptacle 20. The operation of the magnetic resonance device 18 is controlled by a control device 23, the functional design of which is explained in more detail by FIG. 6.

Accordingly, the control device 23 comprises a storage means 24, in which by way of example magnetic resonance sequences, recorded magnetic resonance data, magnetic resonance images reconstructed therefrom, and suchlike can be stored. A configuration unit 25 provides or compiles a magnetic resonance sequence according to step S1, while a sequence unit 26 implements the magnetic resonance sequence by activating the gradient coil arrangement 21 and the radio frequency coil arrangement 22 according to step S2. In other words, the control device 23 is embodied to carry out the inventive method.

Independent of the grammatical term usage, individuals with male, female, or other gender identities are included within the term.

1. A computer-implemented method for recording magnetic resonance data with a magnetic resonance device, comprising:
executing a magnetic resonance sequence having a sequence segment maintained in a steady state by regular excitation modules, each excitation module including at least one excitation pulse;
for each excitation module, providing:
a first read-out time window for measuring magnetic resonance data of a free induction decay; and
a second read-out time window, occurring after a last excitation module by at least a duration of the first read-out time window, the last excitation module acting as a refocusing module for a penultimate excitation module, wherein both read-out time windows immediately follow an excitation module and are used to measure magnetic resonance data of a spin echo; and
outputting, in a preparation period between at least one pair of excitation modules comprising a beginning excitation module and a concluding excitation module that follow one another in the magnetic resonance sequence, a fat saturation module including at least one radio frequency fat saturation pulse.

2. The method of claim 1, wherein the second read-out time window following the concluding excitation module, the first read-out time window preceding the beginning excitation module, or the first read-out window following the concluding excitation module, are omitted, and/or the magnetic resonance data recorded in these read-out time windows is rejected.

3. The method of claim 1, wherein no measurement is performed during the preparation period, and/or wherein a first preparation period of the at least one preparation period is provided immediately after a first output excitation module of each sequence segment, the first output excitation module serving as a beginning excitation module.

4. The method of claim 1, wherein the at least one excitation pulse of each excitation module is configured to restrict the excitation to spins of protons bound in water.

5. The method of claim 1, wherein the fat saturation pulse is output centrally between the beginning and the concluding excitation module, and/or wherein the fat saturation module includes a crusher gradient pulse following the fat saturation pulse.

6. The method of claim 1, wherein each preparation period is provided after a predetermined number of excitation modules.

7. The method of claim 6, wherein the predetermined number of excitation modules is between 10 and 15.

8. The method of claim 1, wherein a preparation period is provided when the center of k-space is traversed in at least one sampling direction.

9. A magnetic resonance device, comprising a control device configured to perform the method of claim 1.

10. A non-transitory electronically readable data carrier having stored thereon a computer program which, when executed by a control device of a magnetic resonance device, causes the control device to perform the method of claim 1.
